(19) United States
(12) Patent Application Publication
(10) Pub. No.: US 2015/0249164 A1
(43) Pub. Date: Sep. 3, 2015

(54) Method of forming functional coatings on silicon substrates

(71) Applicant: OPTITUNE OY, Oulu (FI)

(72) Inventors: Ari Kärkkäinen, Singapore (SG); Milja Hannu-Kuure, Oulu (FI); Henna Järvitalo, Oulu (FI); Paul Williams, Singapore (SG); Jarkko Leivo, Oulu (FI); Admir Hadzic, Oulu (FI); Jianhui Wang, Singapore (SG)

(21) Appl. No.: 14/430,554

(22) PCT Filed: Sep. 24, 2013
(86) PCT No.: PCT/FI2013/050924

§ 371 Date: Mar. 24, 2015

Related U.S. Application Data
(60) Provisional application No. 61/704,747, filed on Sep. 24, 2012.

(30) Foreign Application Priority Data
Sep. 24, 2012 (FI) 20125986

(51) Int. Cl. H01L 31/0216; H01L 31/18

(52) U.S. Cl. CPC H01L 31/02167; H01L 31/02168; H01L 31/1868

(57) ABSTRACT

A method of passivating a silicon substrate, comprising providing a silicon substrate having a surface, forming a stack of passivating and anti-reflection coating layers on said surface by liquid phase deposition, wherein the passivating and anti-reflection coating layers comprise hydrogenated silicon oxide layers, and providing at least titanium oxide or tantalum oxide capping layer on the stack opposite to the silicon substrate surface. The procedure offers an alternative to the existing ALD or PECVD methods using SiH₄ and other gases, enabling the PV manufacturers to apply chemicals rather than work with hazardous gases to produce a series of layers that provide passivation as well as light absorption.

### TECHNICAL FIELD

This invention relates to silicon solar cells. In particular, the present invention concerns a method of passivating a silicon substrate of a solar cell or similar photovoltaic device.

The invention also related to silicon substrates comprising a stack of passivating and anti-reflection coating layers formed on said surface by liquid phase deposition, and at least one capping layer on the stack opposite to the silicon substrate surface.

### BACKGROUND ART

Photovoltaic devices (PV), commonly referred to as solar cells, have historically been manufactured from high purity single crystal, lattice matched semiconductor alloys where, due to the absence of dislocations, very few traps are encountered by free electrons generated in the photo voltaic process. The only traps are located at the surface between the device and air. These traps are generated by the surface configuration of the dangling bonds. These occur where the three dimensional crystallographic nature of the atoms terminates at the air/crystal interface.

To reduce or eliminate these traps, manufacturers have conventionally been using additional thin layers on the front and back surfaces. These additional layers have excellent matching characteristics to the device structure thereby removing the traps from the device.

The passivating layers reduce the carrier recombination at silicon surfaces and therefore result in higher open-circuit voltage, which becomes increasingly important for high-performing solar cells. If applied on the front surface of the solar cells, the passivating layers act as anti-reflective coatings (ARC).

Traditional surface passivation materials include SiOx, SiNx, etc. which are usually prepared using vacuum techniques, such as, thermal oxidation, PECVD, or sputtering. However, due to the complexity of the PECVD and other processes, and the relatively high cost of the manufacturing tools and consumable chemicals and gases, it is of great importance to develop alternative solutions to form dielectric coatings for silicon wafer solar cells. Liquid phase deposition is such a competitive approach which is of comparable passivation quality, cost-effective, and environmental friendly. With that, coatings prepared under atmospheric conditions are possible by eliminating those complex and expensive manufacturing tools.

The invention outlines the methods of deposition, the process and environment conditions of the pretreatment, the conditions and environment of the activation step, along with the invention of the chemical pre-cursors, monomers, polymers and catalysts.

### SUMMARY OF THE INVENTION

The invention is based on the principal of applying a chemical onto the front surface of a PV device to form a thin dielectric layer or layers of thickness ranging from 5 to 250 nm single layer thickness. The formed layer acts as a passivation, hydrogenation and anti-reflection layer for the silicon device.

Upon treating the chemical it is activated and introduces hydrogen into the bulk as well as onto the surface of the PV device. As a result, increasing the efficiency of the current extraction and reduction of recombination occur within the device. This results in greater power output from the device.

More specifically, the present invention concerns a method of passivating a silicon substrate, comprising providing a silicon substrate having a surface; forming a stack of passivating and anti-reflection coating layers on said surface by liquid phase deposition, wherein the passivating and anti-reflection coating layers comprise hydrogenated silicon oxide layers; and providing at least titanium oxide or tantalum oxide capping layer on the stack opposite to the silicon substrate surface.

### Advantageous Effects of Invention

Considerable advantages are obtained. Thus, the procedure offers an alternative to the existing ALD or PECVD method using SiH₄ and other gases, enabling the PV manufacturers to apply chemicals rather than work with hazardous gases to produce a series of layers that provide passivation as well as light absorption.

In the case of thick film solar cell production, the present finding gives rise to a manufacturing sequence in its entirety being performed using chemicals applied under atmospheric conditions and without the use of any hazardous gas or PECVD with the additional benefit of cost reduction and better process control and equipment sustainability.

The embodiments disclosed herein describe the use of hybrid and inorganic chemicals, applied in combination with surface treatments, process, methods of delivery and activation of the chemistry and surface, which results in higher photo-generated minority carrier lifetime, improved light absorption, and subsequent efficiency of the solar device.

### BRIEF DESCRIPTION OF DRAWINGS

FIG. 1 is a schematic representation of a process flow for a p-type crystalline silicon solar cell fabrication with deposition of the chemical onto the front surface of the PV device in absence of vacuum deposited SiNx; and

FIG. 2 is a schematic representation of a process flow for a p-type crystalline silicon solar cell fabrication with deposition of the chemical onto the front surface of the PV device in presence of vacuum deposited SiNx.

### DESCRIPTION OF EMBODIMENTS

As discussed above, the present invention provides a low cost method of improving the electrical and/or optical performance of photovoltaic devices through the application of coating chemicals onto the sunny side of the silicon substrate.

The present method relates to the use of liquid phase processable siloxane and metal-oxide polymer materials in a solar cell manufacturing process. In particular, the invention employs materials which have suitable properties for use as passivation, hydrogenation, and anti-reflection dielectric coatings and which can be applied at the front side of crystalline silicon solar cells.

In particular, the present invention provides a method of applying these materials in crystalline silicon solar cell device fabrication and to a method of producing such coating material compositions.

The passivating, hydrogenating, anti-reflective materials comprise either single or hybrid oxide system which can be deposited onto silicon surface by means of an atmospheric liquid phase chemical coating method. Furthermore the coatings are applied as single or multiple layers on the silicon substrate using one or more different formulations or compositions to deposit each layer.

The present method of passivating a silicon substrate, comprises providing a silicon substrate with or without a layer of vacuum coated SiNx by PECVD or sputter, forming a stack of passivating and anti-reflection coatings thereon via liquid phase deposition, wherein the passivating and anti-reflection coatings comprise a liquid phase deposited hydrogenated silicon oxide and titanium oxide or tantalum oxide capping layer, with or without a vacuum deposited SiNx layer in between.

The passivating layer which hydrogenated silicon oxide provides hydrogen which causes a reduction in the surface and bulk recombination velocity of the silicon substrate. The capping layer with titanium oxide or tantalum oxide improves light absorption by the solar cell due to optical coupling with the layers underneath.

In one embodiment, surface recombination velocity is less than 100 cm/sec.

In another embodiment, the passivating layer comprises silicon, oxygen and hydrogen for p type silicon solar cell substrate.

Typically, there is an anti-reflection layer (or capping layer) which comprises titanium or tantalum, and oxygen for p type silicon substrate.

In a particularly preferred embodiment, the passivating layer is formed by polymerizing Si(OR¹)4 and/or HSi(OR¹)3, wherein R¹ is an alkyl group, preferably a linear or branched alkyl group having 1 to 8 carbon atoms, in particular a linear or branched alkyl group having 1 to 4 carbon atoms. Advantageously, the alkoxy group is methoxy or ethoxy.

The passivating layer is formed by polymerizing Ti(iOPr)₄, HSi(OR¹)₃ and TiCl₄ (for titanium oxide); by polymerizing Ta(iOPr)₅, HSi(OR¹)₃ and TaCl₅ (for tantalum oxide) or the passivating layer is formed by polymerizing HSi(OR¹)₃ and Al(iOPr)₃ (for aluminium oxide and silicon oxide hybrid).

The passivating layer, produced by any of the above embodiments, is capable of reducing the number of dangling bonds on the surface and bulk of the silicon substrate upon which the passivating layer is formed.

The anti-reflection layer is capable of increasing the absorption on a surface of the silicon substrate upon which the passivating layer is formed.

As discussed above, liquid phase deposition of the passivating layer is preferably performed at atmospheric pressure. The liquid phase coating is carried out by a method selected from the group of dip coating, slot coating, roller coating and spray coating and combinations thereof.

The silicon substrate, such as silicon wafer is part of a photovoltaic cell.

The photovoltaic cell is part of a photovoltaic panel/module.

The photovoltaic cell array is laminated with cover glass with thickness ranging from 1 mm to 4 mm.

The photovoltaic cell array is laminated with cover glass that is anti-reflection coated to further improve the efficiency of the photovoltaic cell.

The photovoltaic cell is manufactured using only atmospheric manufacturing processes.

The passivating and anti-reflection coatings or capping layers are preferably formed without a SiNx layer in between the coatings or capping layers, respectively.

However, it is also possible to vacuum depositing at least one SiNx layer in between the passivating and anti-reflection coatings or to vacuum depositing at least one SiNx layer in between the capping layers. In another embodiment, at least one SiNx layer is deposited by PECVD or sputtering.

In respect to the above discussion on hydrogenation and passivation, it should be pointed out that positively charged SiOx is well suitable for passivation for the emitter (sunny side) of p-type solar cell and for the back side of n-type solar cell due to the formation of accumulation layer through surface band-bending. Hydrogenation from SiOx further reduces both surface and bulk recombination velocity through chemical passivation of defects, which ties up the dangling bonds and reduces Dit (density of interface states).

Aluminium oxide is a highly negatively charged dielectric which provides excellent passivation for the back side of p-type solar cell or for the front side of n-type solar cell by forming an accumulation layer by surface field effect (band-bending).

With AlOx deposited on the back side of p-type solar cell, improved passivation is achieved compared to Al—BSF, while avoiding the parasitic shunting that would occur from using positively charged SiOx or SiNx.

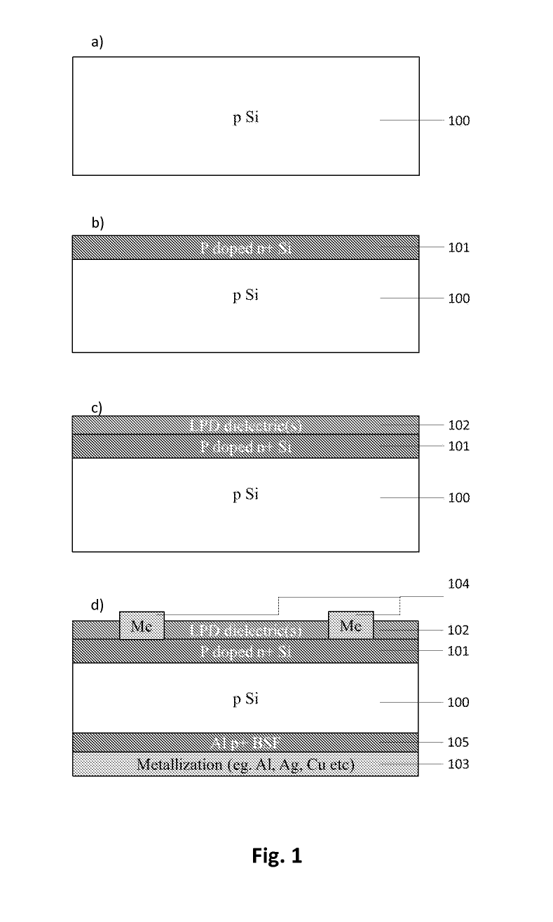

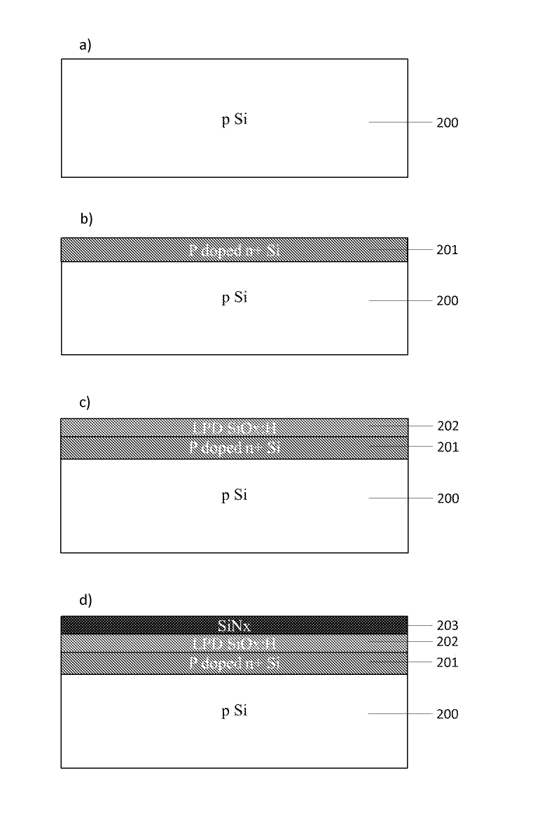

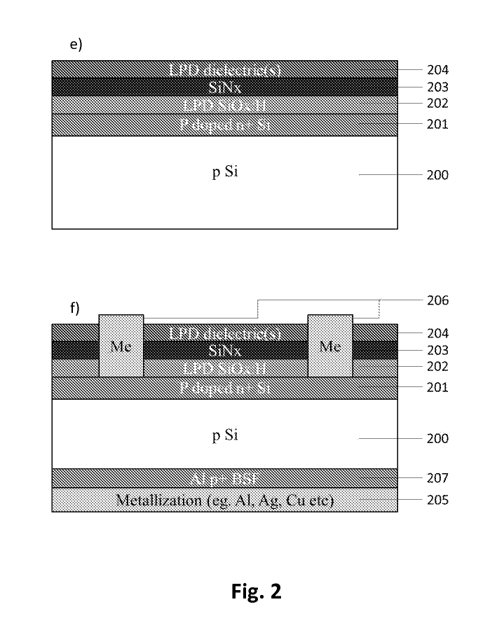

FIGS. 1 and 2 illustrate the steps for fabricating silicon wafer solar cells incorporating liquid phase deposited dielectrics at the front side of the device.

Turning first to FIGS. 1a to 1d, it can be noted that there are depicted cross sectional views showing the process flow for manufacturing a p-type crystalline silicon solar cell incorporating therein dielectric(s) in accordance with a preferred embodiment of the present invention without vacuum deposited SiNx.

The process for fabricating the silicon solar cell begins with a boron doped p-type silicon substrate 100 which is saw-damage etched, textured and cleaned using wet chemicals. The substrate 100 undergoes either batch or inline doping and diffusion with phosphorous bearing chemical source, which results into a negative phosphorous doped region 101. The doped region 101 could also be achieved with other doping techniques, such as ion implantation. Phosphorus silica glass (PSG) formed during diffusion is removed prior to the liquid phase deposited (LPD) dielectrics 102. Edge isolation of the solar cell could either be accomplished before deposition of dielectrics 102 or after metallization at later stage. Dielectrics 102 comprise a first layer of hydrogenated silicon oxide, and capping layer of titanium oxide or tantalum oxide or similar which provides anti-reflection coupled with hydrogenated silicon oxide. The dielectrics 102 can be deposited by using any wet chemical process methods including (but not limited to) spray coating, roller coating, ink-jet, dip coating, spin coating, slot coating. The dielectric 102 can be deposited as a full area film or alternatively can be deposited or processed to form a pattern on the silicon wafer surface. Following this, screen printing, inkjet printing, direct printing, physical vapor deposition (PVD), plating or other metallization methods are applied to form metal 103 (eg. aluminium, silver, copper, or etc) at the back and metal grids 104 at the front (eg. silver, copper or etc). In case of aluminium used for metal 103, back surface field (BSF) 105 is formed during co-firing step which is also required to fire through the contact at the front, and enhance hydrogenation from dielectrics 102.

Referring to FIGS. 2a to 2f, there are cross sectional views provided showing the process flow for manufacturing a p-type crystalline silicon solar cell incorporating therein dielectric(s) in accordance with a preferred embodiment of the present invention combined with vacuum deposited SiNx. The process for fabricating the silicon solar cell begins with a boron doped p-type silicon substrate 200 which is saw-damage etched, textured and cleaned using wet chemicals. The substrate 200 undergoes either batch or inline doping and diffusion with phosphorous bearing chemical source, which results into a negative phosphorous doped region 201. The doped region 201 could also be achieved with other doping techniques, such as ion implantation. Phosphorus silica glass (PSG) formed during diffusion is removed prior to the liquid phase deposited (LPD) dielectrics 202. Edge isolation of the solar cell could either be accomplished before deposition of dielectrics 202 or after metallization at later stage. Dielectric 202 is a layer of hydrogenated silicon oxide which provides hydrogenation to the surface and bulk of silicon upon thermal treatment. The dielectrics 202 can be deposited by using any wet chemical process methods including (but not limited to) spray coating, roller coating, ink-jet, dip coating, spin coating, slot coating. The dielectric 202 can be deposited as a full area film or alternatively can be deposited or processed to form a pattern on the silicon wafer surface. Silicon nitride 203 is deposited either by PECVD or sputtering under vacuum conditions to provide both anti-reflection and passivation to the silicon device. Optionally a layer of titanium oxide or tantalum oxide or similar 204 is capping on the top of SiNx 203 to further enhance light absorption. Following this, screen printing, inkjet printing, direct printing, physical vapor deposition (PVD), plating or other metallization methods are applied to form metal 205 at the back (eg. aluminium, silver, copper or etc) and metal grids 206 at the front (eg. silver, copper or etc). In case of aluminium used for metal 205, back surface field (BSF) 207 is formed during co-firing step which is also required to fire through the contact at the front, and enhance hydrogenation from dielectrics 202 and 203.

As an example of a solar cell fabricated using the method described in FIG. 1, a boron doped p-type float zone (FZ) mono-crystalline silicon wafer of (100) orientation is used as the substrate for solar cell device. Thickness of the substrate is below 250 μm. The bulk resistivity of the silicon wafer is 0.5-2.5 Ω·m. Silicon wafer is saw damage etched, and alkaline textured at one side with pyramid size of 1-10 μm. Textured wafer undergoes POCl3 diffusion to form an emitter of sheet resistance at 50-100Ω/□. Typical diffusion temperature is 750-950° C. Parasitic PSG and junction formed at the back surface during diffusion are removed using mixture of nitric acid (HNO₃) and hydrofluoric acid (HF). Multiple layers of hydrogenated silicon oxide (SiOx), coupled with titanium oxide (TiOx) and/or tantalum oxide (TaOx) and/or aluminum oxide (AlOx) in the range of 5-250 nm each are deposited at the sunny side as anti-reflection and hydrogenation passivation coatings. The refractive index of SiOx is from 1.35 to 1.60. The refractive index of TiOx is from 2.0 to 2.80 at the wavelength of 633 nm. The refractive index of TaOx is from 1.8 to 2.5 at the wavelength of 633 nm. The refractive index of AlOx is from 1.5 to 1.8 at the wavelength of 633 nm. The thickness and refractive index of the dielectric coatings are selected in such way that optimum hydrogenation and anti-reflection effect is achieved. It is possible to use multiple layers of hydrogenation passivation and anti-reflective coatings to optimize performance. A layer of aluminium paste is screen printed and dried at the back surface of the solar device. The thickness of the aluminium paste is chosen from 10-50 μm to ensure a maximum amount of Al-BSF formation at later stage, and minimum level of wafer warpage on the other hand. Silver grids and busbars are then screen printed and dried to form the metal contacts. In the final step, a belt firing furnace is used to fire the silver fingers through the dielectrics at the front, form the Al—BSF, and enhance and activate surface and bulk hydrogenation and passivation. The peak temperature of the firing step is from 700-900° C. With the hydrogenation passivation, anti-reflection coating materials and method described, emitter saturation current (Joe)<300 fA/cm2 can been achieved for n+ emitter of 70Ω/square sheet resistance, in comparison to a typical Joe of 100-200 fA/cm2 for PECVD SiNx on 70Ω/square n+ emitter using FZ silicon. Comparable reflectance is achieved.

As another example of a solar cell fabricated using the method described in FIG. 2, a boron doped p-type float zone (FZ) mono-crystalline silicon wafer of (100) orientation is used as the substrate for solar cell device. Thickness of the substrate is below 250 μm. The bulk resistivity of the silicon wafer is 0.5-2.5 Ω·cm. Silicon wafer is saw damage etched, and alkaline textured at one side with pyramid size of 1-10 μm. Textured wafer undergoes POCl₃ diffusion to form an emitter of sheet resistance at 50-100Ω/□. Typical diffusion temperature is 750-950° C. Parasitic PSG and junction formed at the back surface during diffusion are removed using mixture of nitric acid (HNO3) and hydrofluoric acid (HF). Multiple layers of hydrogenated silicon oxide (SiOx), coupled with titanium oxide (TiOx) and/or tantalum oxide (TaOx) and/or aluminum oxide (AlOx) in the range of 5-250 nm each are deposited at the sunny side as anti-reflection and hydrogenation passivation coatings. The refractive index of SiOx is from 1.35 to 1.60. The refractive index of TiOx is from 2.0 to 2.80 at the wavelength of 633 nm. The refractive index of TaOx is from 1.8 to 2.5 at the wavelength of 633 nm. The refractive index of AlOx is from 1.5 to 1.8 at the wavelength of 633 nm. The thickness and refractive index of the dielectric coatings are selected in such way that optimum hydrogenation and anti-reflection effect is achieved. It is possible to use multiple layers of hydrogenation passivation and anti-reflective coatings to optimize performance. An additional PECVD SiNx layer is sandwiched in between a SiOx hydrogenation layer and TiOx, TaOx or AlOx to further improve passivation and anti-reflection by providing hydrogenation and optical coupling. The thickness and RI of SiNx are 10-90 nm and 2.0 respectively. A layer of aluminium paste is screen printed and dried at the back surface of the solar device. The thickness of the aluminium paste is chosen from 10-50 μm to ensure a maximum amount of Al—BSF formation at later stage, and minimum level of wafer warpage on the other hand. Silver grids and busbars are then screen printed and dried to form the metal contacts. In the final step, a belt firing furnace is used to fire the silver fingers through the dielectrics at the front, form the Al—BSF, and enhance surface and bulk hydrogenation. The peak temperature of the firing step is from 700-900° C. With the hydrogenation, anti-reflection coating materials and method described, emitter saturation current (Joe) as low as <300 fA/cm2 has been achieved for a textured phosphorus diffused n+ emitter, in comparison to a Joe of 100-200 fA/cm2 for PECVD SiNx on same substrate. Based on comparison of cell electrical data between MH hydrogenation material supplied by Optitune and standard PECVD SiNx, MH hydrogenation coating is able to improve both short circuit current (Isc) and open circuit voltage (Voc) by 1.4% and 0.6% respectively, which is equivalent to 1.9% of cell and module power gain.

All typical process parameters for the example are listed in Table 1.

Table 1 lists process parameters for p-type screen printed solar cell using LPD dielectrics at the front compared to that using PECVD SiNx

| | | | | (LPD AR + |
|---|---|---|---|---|
| | | LPD dielectrics | (PECVD SiN + | PECVD SiN + |
| | PECVD SiNx | (AR + MH) | MH) | MH) |
| Substrate material | p-type (100) FZ, | p-type (100) | p-type (100) | p-type (100) |
| | 1.5 Ω · cm | FZ, 1.5 Ω · cm | FZ, 1.5 Ω · cm | FZ, 1.5 Ω · cm |
| Wafer thickness, μm | 200 | 200 | 200 | 200 |
| Emitter Rsh, Ω/sq | 70 | 70 | 70 | 70 |
| LPD SiOx thickness, | NA | 10 | 10 | 10 |
| nm | | | | |
| LPD SiOx RI @ 633 nm | NA | 1.45 | 1.45 | 1.45 |
| SiNx thickness, nm | 75 | NA | 70 | 10 |
| SiNx RI @ 633 nm | 2.0 | NA | 2.0 | 2.0 |
| LPD TiOx thickness, | NA | 30 | NA | 25 |
| nm | | | | |
| LPD TiOx RI @ | NA | 2.50 | NA | 2.50 |
| 633 nm | | | | |
| LPD TaOx thickness, | NA | 30 | NA | 25 |
| nm | | | | |
| LPD TaOx RI @ 633 nm | NA | 1.90 | NA | 1.90 |

In a preferred embodiment, the functional layers, which also can be called hydrogen releasing and passivating layers, are formed from siloxane/silane polymers, hybrid organic-inorganic polymers or carbosilane polymers. The polymers can be produced from various intermediates, precursors and monomers.

Furthermore, the above mentioned polymers contain at least one monomer, precursor or polymer that has a group or a substituent or a part of the molecules that has a hydrogen atom, and which capable of releasing that hydrogen atom, in particular in subsequent processing steps of the functional layer in solar cell manufacturing process. The hydrogen releasing monomer can be a silane precursor, for example trimethoxysilane, triethoxysilane (generally any trialkoxysilane, wherein alkoxy has 1 to 8 carbon atoms), a trihalosilane, such as trichlorosilane, or similar silanes, in particular of the kind which contain at least one hydrogen after hydrolysis and condensation polymerization. It can be used as monomeric additive in the coating material or hydrolyzed and condensated as part of the material backbone matrix. Also other silane types can be used as hydrogen releasing entities, including bi-silanes, and carbosilanes which contain hydrogen moiety. Generally, it is required that the hydrogen releasing group or substituent or part of the molecule contains a hydrogen which is bonded to a metal or a semimetal atom, preferably to a metal or a semimetal atom in the polymeric structure forming the layer. The hydrogen can also be bonded to a carbon atom, provided that the hydrogen is released upon treatment of the functional layers.

Hybrid organic-inorganic polymers can be synthesized by using silane or metal (or semimetal) oxide monomers or, and in particular, combinations of silane and metal oxide monomers as starting materials. Furthermore, the final coating chemical (precursor, monomer, polymer, intermediate, catalyst or solvent) has hydrogen moiety in the composition and that hydrogen being able to be released then during the solar cell manufacturing process to provide hydrogenation and passivation qualities. The polymers and intermediates have a siloxane backbone comprising repeating units of —Si—C—Si—O and/or —Si—O— and/or —Si—C—Si—C. Generally, in the formula (—Si—O—)ₙ and in the formula (—Si—C—Si—O—)ₙ and in the formulas (—Si—C—)ₙ the symbol n stands for an integer 4 to 10,000, in particular about 10 to 5000. In the case of using hybrid silane and metal oxide monomers the polymer and intermediates have a backbone comprising repeating units—Si—O-Me—O (where Me indicates metal atom such as Ti, Ta, Al or similar). The hybrid silane—metal oxide backbone can be also different to this.

Hybrid organic-inorganic polycondensates can be synthesized by using metal alkoxides and/or metal salts as metal precursors. Metal precursors are first hydrolysed, and metal alkoxides are typically used as the main source for the metal precursors. Due to the different hydrolysis rate, the metal alkoxides must be first hydrolysed and then chelated or otherwise inactivated in order to prevent self-condensation into monocondensate Me-O-Me precipitates. In the presence of water, this can be controlled by controlling the pH, which controls the complex ions formation and their coordination. For example, aluminum can typically form four-fold coordinated complex-ions in alkaline conditions and six-fold coordinated complex-ions in acidic conditions. By using metal salts as co-precursors, such as nitrates, chlorides, sulfates, and so on, their counter-ions and their hydrolysable metal complex-ions can conduct the formation of different coordination states into the final metal precursor hydrolysate.

Once a hydrolysed metal precursor is achieved, the next step is to introduce the silica species into the chelated or inactivated metal precursor solution. Silica sources are first dissolved and hydrolysed, at least partially, either directly in the metal precursor solution or before its introduction into the metal precursor solution. During or after the introduction, the partially or fully hydrolysed silica species are then let to react with the metal hydrolysate to form a polycondensate. The reaction can be catalyzed by altering the temperature, concentration, temperature, and so on, and it typically occurs at higher temperatures than room temperature. Due to the nature of metal complex-ions in general, it is often common that the polycondensates resembles rather a nanoparticulate structure than a linear polymer, which therefore has to be further electrochemically or colloidally stabilized to sustain its nanosized measures in the coating solution. During processing, the solution further forms a coating that will have its final degree of condensation after heat-treatment, where the major part of rest of the hydrolyzed groups are removed.

Again for example triethoxysilane (or another one of the above mentioned monomers) can be used as the hydrogen releasing moiety in the material. The Triethoxysilane is hydrolyzed and condensation polymerized example with the metal (semimetal) alkokside to results in final product. It is also possible to make the synthesis from halogenide based precursor and other types as well.

In the polymeric structures disclosed above, there is preferably a releasable hydrogen directly bonded to a metal or semimetal atom.

There can be up to one releasable hydrogen attached to each repeating metal or semimetal atom of the backbone.

The precursor molecules of the siloxane and/or metal (semimetal) oxide polymers can be penta-, tetra-, tri-, di-, or mono-functional molecules. A penta-functional molecule has five hydrolysable groups; tetra-functional molecule has four hydrolysable groups; a tri-functional molecule has three hydrolysable groups; a di-functional molecule has two; and mono-functional molecule has one. The precursor molecules, i.e. silane and metal oxide monomers can be have organic functionalities. The precursor molecules can be also bi-silanes and especially in case of some metal oxide or hybrid metal oxide it is possible to use some stabilizing agents in the composition in addition to other additives and catalyst. The molecular weight range for the siloxane and/or metal oxide coating material is in range of 400 to 150,000, preferably about 500 to 100,000, in particular about 750 to 50,000 g/mol.

A wet chemical coating is prepared from the coating solution by any typical liquid application (coating) processes, preferably with spin-on, dip, spray, ink-jet, roll-to-roll, gravure, flexo-graphic, curtain, drip, roller, screen printing coating methods, extrusion coating and slit coating, but are not limited to these.

According to one embodiment, the process according to the invention comprises hydrolyzing and polymerizing a monomers according to either or both of formulas I and II:

R¹ₐSiX₄₋ₐ I

and

R²_{b}SiX_{4-b} II
wherein R¹ and R² are independently selected from the group consisting of hydrogen, linear and branched alkyl and cycloalkyl, alkenyl, alkynyl, (alk)acrylate, epoxy, allyl, vinyl and alkoxy and aryl having 1 to 6 rings; each X represents independently halogen, a hydrolysable group or a hydrocarbon residue; and
   a and b is an integer 1 to 3.

Further, in combination with monomers of formula I or II or as such at least one monomer corresponding to Formula III can be employed:

R³_{c}SiX_{4-c} III
wherein R³ stands for hydrogen, alkyl or cycloalkyl which optionally carries one or several substituents, or alkoxy;
   each X represents independently halogen, a hydrolysable group or a hydrocarbon residue having the same meaning as above; and
   c is an integer 1 to 3.

In any of the formulas above, the hydrolysable group is in particular an alkoxy group (cf. formula IV).

As discussed above, in the present invention organosiloxane polymers are produced using tri- or tetraalkoxysilane. The alkoxy groups of the silane can be identical or different and preferably selected from the group of radicals having the formula wherein R⁴ stands for a linear or branched alkyl group having 1 to 10, preferably 1 to 6 carbon atoms, and optionally exhibiting one or two substitutents selected from the group of halogen, hydroxyl, vinyl, epoxy and allyl.

The above precursor molecules are condensation polymerized to achieve the final siloxane polymer composition. Generally, in case of tri-, di- and mono-functional molecules, the other functional groups (depending on the number of hydrolysable group number) of the precursor molecules can be organic functionalities such as linear, aryl, cyclic, aliphatic groups. These organic groups can also contain reactive functional groups e.g. amine, epoxy, acryloxy, allyl or vinyl groups. These reactive organic groups can optionally react during the thermal or radiation initiated curing step. Thermal and radiation sensitive initiators can be used to achieve specific curing properties from the material composition.

According to a preferred embodiment, when using the above monomers, at least one of the monomers used for hydrolysation and condensation is selected from monomers having formulas I or II, wherein at least one substituent is a group capable of providing the hydrogenation and passivation characteristics for the coated film. For preparing the prepolymer, the molar portion of units derived from such monomers (or the molar portion of monomers containing the active group calculated from the total amount of monomers) is about 0.1 to 100%, preferably about 20%-100%, in particular about 30% to 100%. In some cases, the group will be present in a concentration of about 30% based on the molar portion of monomers.

In the above polymers, the relation (molar ratio) between monomers providing releasable hydrogens in the polymeric material and monomers which do not contain or provide such hydrogens is preferably 1:10, in particular 5:10, preferably 10:10-1000:10. It is possible even to employ only monomers leaving a releasable hydrogen for the production of the polymer.

The carbosilane polymer can be synthesized for example by using Grignard coupling of chloromethyltrichlorosilane in the presence THF followed by reduction with lithium aluminum hydride. A general reaction route is given below. The end product contains two hydrogens bonded to the silicon atom which are capable being released during the processing of the silicon solar cell. The final product is dissolved in a processing solvent and can be processed as is using the liquid phase deposition. The final product can be used also as dopant, additive or reacted with silane or metal (or semimetal) backbone to results as coating material.

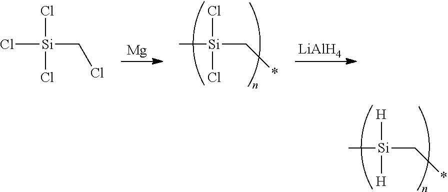

According to a preferred embodiment, when using the above monomers, at least one of the monomers used for hydrolysation and condensation is selected from monomers having formulas I or II, wherein at least one substituent is a group capable of providing the hydrogenation and passivation characteristics for the coated film. For preparing the prepolymer, the molar portion of units derived from such monomers (or the molar portion of monomers containing the active group calculated from the total amount of monomers) is about 0.1 to 100%, preferably about 20% to 100%, in particular about 30% to 100%. In some cases, the group will be present in a concentration of about 30% based on the molar portion of monomers.

According to one embodiment, at least 50 mol-% of the monomers are being selected from the group of tetraethoxysilane, triethoxysilane, tetramethoxysilane, trimethoxysilane, tetrachlorosilane, trichlorosilane, and mixtures thereof.

According to one embodiment, the solution coating polymer composition comprises a siloxane polymer, hybrid silane metal oxide polymer or carbosilane polymer in a solvent phase, wherein the partially cross-linked prepolymer has a siloxane or hybrid silane metal oxide or carbosilane backbone formed by repeating units and having a molecular weight in the range of from about 1,000 to about 15,000 g/mol, for example 2,000 to 10,000 g/mol. In addition, the (pre)polymer backbone exhibits 1 to 100 releasable hydrogen per 100 repeating units.

According to another embodiment, the siloxane composition comprises a siloxane polymer, hybrid silane metal oxide polymer or carbosilane polymer in a solvent phase, wherein
the partially cross-linked prepolymer has a siloxane backbone formed by repeating —Si—O— units and having a molecular weight in the range of from about 4,000 to about 10,000 g/mol, the siloxane backbone exhibiting hydroxyl groups in an amount of about 5 to 70% of the —Si—O— units and further exhibiting epoxy groups in an amount of 1 to 15 mol %, calculated from the amount of repeating units; and
the composition further comprises 0.1-3%, based on the weight of the solid matter, at least one cationic photo reactive compound.

The synthesis of the siloxane polymer is carried out in two steps. In the first synthesis step, in the following also called the hydrolysis step, the precursor molecules are hydrolyzed in presence typically of water and a catalyst, such as hydrochloric acid or nitric acid or another mineral or organic acid or a base, and in the second step, the polymerization step, the molecular weight of the material is increased by condensation polymerization or other crosslinking depending on what precursors are chosen to the synthesis. The water used in the hydrolysis step has typically a pH of less than 7, preferably less than 6, in particular less than 5.

It may be preferable in some cases to carry out the condensation polymerization in the presence of a suitable catalyst. In this step the molecular weight of the prepolymer is increased to facilitate suitable properties of the material and film deposition and processing.

The siloxane polymer synthesis, including the hydrolysis, the condensation and the cross-linking reactions, can be carried out using an inert solvent or inert solvent mixture, such as acetone or PGMEA, “non-inert solvent”, such as alcohols, or without a solvent. The used solvent affects the final siloxane polymer composition. The reaction can be carried out in basic, neutral or acidic conditions in the presence of a catalyst. The hydrolysis of the precursors may be done in the presence of water (excess of water, stoichiometric amount of water or sub-stoichiometric amount of water). Heat may be applied during the reaction and refluxing can be used during the reaction.

Typically before the further condensation the excess of water is removed from the material and at this stage it is possible to make a solvent exchange to another synthesis solvent if desired. This other synthesis solvent may function as the final or one of the final processing solvents of the siloxane polymer. The residual water and alcohols and other by-products may be removed after the further condensation step is finalized. Additional processing solvent(s) may be added during the formulation step to form the final processing solvent combination. Additives such as thermal initiators, radiation sensitive initiators, surfactants and other additives may be added prior to final filtration of the siloxane polymer. After the formulation of the composition, the polymer is ready for processing.

Suitable solvents for the synthesis are, for example, acetone, tetrahydrofuran (THF), toluene, 1-propanol, 2-propanol, methanol, ethanol, propylene glycol monomethyl ether, propylene glycol propyl ether, methyl-tert-butylether (MTBE), propylene glycol monomethylether acetate (PGMEA), propylene glycol monomethylether PGME and propylene glycol propyl ether (PnP), PNB, IPA, MIBK, Glycol Ethers (Oxitols, Proxitols), Butyl Acetates, MEK Acetate, or mixtures of these solvents or other suitable solvents.

After synthesis, the material is diluted using a proper solvent or solvent combination to give a solid content and coating solution properties which with the selected film deposition method will yield the pre-selected film thickness. Suitable solvents for the formulation are example 1-propanol, 2-propanol, ethanol, propylene glycol monomethyl ether, propylene glycol propyl ether (PNP), PNB (propandiol-monobutyl ether), methyl-tert-butylether (MTBE), propylene glycol monomethylether acetate (PGMEA), propylene glycol monomethylether PGME and PNB, IPA, MIBK, Glycol Ethers (Oxitols, Proxitols), Butyl Acetates, MEK Acetate, or mixtures of these solvents or other suitable solvents.

The final coating film thickness has to be optimized according for each device and structure fabrication process. In addition to using different solvents it is also possible to use surfactants and other additives to improve the coating film quality, wetting and conformality on the silicon cell.

Optionally, an initiator or catalyst compound is added to the siloxane composition after synthesis. The initiator, which can be similar to the one added during polymerization, is used for creating a species that can initiate the polymerization of the “active” functional group in the UV curing step. Thus, in case of an epoxy group, cationic or anionic initiators can be used. In case of a group with double bonds as “active” functional group in the synthesized material, radical initiators can be employed. Also thermal initiators (working according to the radical, cationic or anionic mechanism) can be used to facilitate the cross-linking of the “active” functional groups. The choice of a proper combination of the photoinitiators also depends on the used exposure source (wavelength). Also photoacid generators and thermal acid generators can be used to facilitate improved film curing. The concentration of the photo or thermally reactive compound in the composition is generally about 0.1 to 10%, preferably about 0.5 to 5%, calculated from the mass of the siloxane polymer.

Film thicknesses may range e.g. from 1 nm to 500 nm. Various methods of producing thin films are described in U.S. Pat. No. 7,094,709, the contents of which are herewith incorporated by reference.

A film produced according to the invention typically has an index of refraction in the range from 1.2 to 2.4 at a wavelength of 633 nm.

The composition as described above may comprise solid nanoparticles in an amount between 1 and 50 wt-% of the composition. The nanoparticles are in particular selected from the group of light scattering pigments and inorganic phosphors or similar. By means of the invention, materials are provided which are suitable for producing films and patterned structures on silicon cells. The patterning of the thermally and/or irradiation sensitive material compositions can be performed via direct lithographic patterning, laser patterning and exposure, conventional lithographic masking and etching procedure, imprinting, ink-jet, screen-printing and embossing, but are not limited to these.

The compositions can be used for making layers which are cured at relatively low processing temperatures, e.g. at a temperature of max 375° C. or even at temperature of 100° C. and in the range between these limits.

However the coating layer formed from the material compositions can also be cured at higher temperatures, i.e. at temperatures over 375° C. and up to 900° C., or even up to 1100° C., making it possible for the material films or structures to be cured at a high temperature curing, such as can be combined with a subsequent high temperature deposition and firing steps.

In the following, the invention will be illustrated with the aid of a number of working examples giving further details of the preparation of the above-discussed siloxane polymer, hybrid silane-metal oxide polymer and carbosilane coating compositions.

In the following, there is presented a number of non-limiting working examples giving further details of the preparation of the above-discussed siloxane polymer, hybrid silane-metal oxide polymer and carbosilane coating compositions, suitable for forming passivating and hydrogen-releasing layers on silicon substrates in photovoltaic devices. These materials can be applied as discussed above in connection with the drawings.

### EXAMPLE 1

Tetraethyl orthosilicate (28.00 g) and Triethoxysilane (42.00 g) and solvent (ethanol) were weighted into the 1 L flask and stirred for 30 minutes. 0.01 M HCl (2× equivalent) was added. Material was refluxed for one hour. Solvent exchange was done to propylene glycol propyl ether (PnP). A further condensation polymerization was carried out in presence of catalyst (triethylamine). After this trimethylmethoxysilane (0.02 g) was added and further solvent exchange done to propylene glycol propyl ether (PnP). Material was diluted to process formulation and filtrated with 0.1 μm filter to obtain process ready solution.

### EXAMPLE 2

Tetraethyl orthosilicate (14.00 g) and Triethoxysilane (60.00 g) and solvent (2-propanol) were weighted into the 1 L flask and stirred for 30 minutes. 0.01 M HCl (0.6 equivalent) was added. Material was refluxed for one hour. Solvent exchange was done to propandiol-monobutyl ether (PNB). A further condensation polymerization was carried out in presence of catalyst (triethylamine). After this trimethylmethoxysilane (0.021 g) was added and further solvent exchange done to propylene glycol propyl ether (PnP). Material was diluted to process formulation and filtrated with 0.1 μm filter to obtain process ready solution.

### EXAMPLE 3

Methyl-trimethoxysilane (15.00 g), 3-Glycidoxypropyl-trimethoxysilane (9.00 g) and Triethoxysilane (75.00 g) and solvent (2-propanol) were weighted into the 1 L flask and stirred for 30 minutes. 0.01 M HCl (1 equivalent) was added. Material was refluxed for one hour. Solvent exchange was done to propylene glycol propyl ether (PnP). A further condensation polymerization was carried out in presence of catalyst (triethylamine). After this trimethylethoxysilane (0.025 g) was added and further solvent exchange done to propylene glycol propyl ether (PnP). Material was diluted to process formulation and filtrated with 0.1 μm filter to obtain process ready solution.

### EXAMPLE 4

Tetraethyl orthosilicate (5.00 g) and Triethoxysilane (82.00 g) and solvent (2-propanol) were weighted into the 1 L flask and stirred for 30 minutes. 0.01 M HCl (1 equivalent) was added. Material was refluxed for one hour. Solvent exchange was done to propylene glycol propyl ether (PnP). A further condensation polymerization was carried out in presence of catalyst (triethylamine). After this trimethylethoxysilane (0.025 g) was added and further solvent exchange done to propylene glycol propyl ether (PnP). Material was diluted to process formulation and filtrated with 0.1 μm filter to obtain process ready solution.

### EXAMPLE 5

Triethoxysilane (98.00 g) and solvent (2-propanol) were weighted into the 1 L flask and stirred for 30 minutes. 0.01 M HCl (0.6 equivalent) was added. Material was refluxed for one hour. Solvent exchange was done to propylene glycol propyl ether (PnP). A further condensation polymerization was carried out in presence of catalyst (triethylamine). After this trimethylchlorosilane (0.02 g) was added and further solvent exchange done to propylene glycol propyl ether (PnP). Material was diluted to process formulation and filtrated with 0.1 μm filter to obtain process ready solution.

### EXAMPLE 6

Aluminium nitrate-nonahydrate (180 g) in water solution was mixed with Aluminium isopropoxide (80g). After that triethoxysilane (15 g) was added. Solution was refluxed for 4 hours. 1-propanol was added as processing solvent and filtrated with 0.1 μm filter to obtain process ready solution.

### EXAMPLE 7

Aluminium nitrate-nonahydrate (180 g) in water solution was mixed with Aluminium isopropoxide (40 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 8

Aluminium nitrate-nonahydrate (180 g) in water solution was mixed with Aluminium isopropoxide (20 g) and Titanium isopropoxide (25 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 9

Aluminium nitrate-nonahydrate (180 g) in water solution was mixed with Titanium (IV) isopropoxide (38 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 10

Aluminium nitrate-nonahydrate (180 g) in water solution was mixed with Aluminium isopropoxide (20 g) and Tantalum ethoxide (22 g). After that triethoxysilane (15 g) was added. Solution was refluxed for 4 hours. Solvent exchanged was performed to 1-propanol. The solution was filtrated with 0.1 μm filter to obtain process ready solution.

### EXAMPLE 11

Aluminium nitrate-nonahydrate (180 g) in water solution was mixed with Aluminium isopropoxide (35 g). After that tetraethyl orthosilicate (5 g) and triethoxysilane (14 g) was added. Solution was refluxed for 4 hours. Solvent exchanged was performed to 1-propanol. The solution was filtrated with 0.04 μm filter to obtain process ready solution.

### EXAMPLE 12

20 g of Aluminium s-butoxide and 200 g of PGEE were mixed for 30 min. 15.58 g of Ethyl Acetoacetate was added and followed by addition of triethoxysilane (11 g) was added and mixed. Mixture of H₂O and PGEE (8 g and 40 g) was added. The solution was filtrated with 0.1 μm filter to obtain process ready solution.

### EXAMPLE 13

20 g of AlCl₃ was dissolved to EtOH (200 g) and TiCl₄ (10 g)+Ti(iOPr)₄ (14 g) was dissolved to 200 g of EtOH. Dissolved solutions were combined. Solution was stirred for 60 min at RT. Triethoxysilane (15 g) was added and solution was strirred at RT for 60 min. EtOH was distilled using membrane pump. 220 g of 2-isopropoxyethanol was added to the material flask. Solution was cooled down and filtrated. Solution was formulated to the final processing solvent 1-butanol and was filtrated with 0.1 μm filter to obtain process ready solution.

### EXAMPLE 14

Mg (8 g) was charged in reactor flask and the atmosphere was changed from air to N₂. Dry THF (175 ml) was added to Mg and Cl₃SiCH₂Cl (35 mL) was added at RT. Solution was refluxed for 4 hours. The reaction mixture was washed with dry THF and LiAlH₄ was added (4.0 grams). The solution was refluxed for 2 hours. The solvent was changed to pentane and extracted (300-400 mL). The solution was filtrated and solvent exchange was made to propylene glycol propyl ether (PnP). Material was diluted to process formulation and filtrated with 0.1 μm filter to obtain process ready solution.

### EXAMPLE 15

Mg (12 g) was charged in a reactor flask and the atmosphere was changed from air to N₂. Dry THF was added to Mg and Cl₃SiCH₂Cl (35 mL) was added at RT. CuCN was added to the reaction mixture. Solution was refluxed for 4 hours. The reaction mixture was washed with dry THF and LiAlH₄ was added (4.0 grams). The solution was refluxed for 2 hours. The solvent was changed to pentane and extracted (300-400 mL). The solution was filtrated and solvent exchange was made to propylene glycol propyl ether (PnP). The material was diluted to process formulation and filtrated with 0.1 μm filter to obtain process ready solution.

### EXAMPLE 16

Basic recipe: Place 704 grams of Titanium (IV) isopropoxide to reactor flask. Add 470 grams of titanium tetrachloride to reactor. Add 5760 ml of methanol to the reactor and stir the reaction solution for 2 hours.

MeOH was distilled using membrane pump, distillation apparatus and oil bath. 5872 grams of 2-isopropoxyethanol was added to the material flask. The solution was cooled down to −6° C. 1013 g of TEA was added the way that the material solution temperature was kept between −6° C. and +6° C. during TEA addition. The solution was filtrated using a Buchner funnel. The solution was cooled down in the reactor over night. Finally the solution was filtrated using a filter paper. The solution was formulated to the final processing solvent IPA and was ready for processing after final filtration.

### EXAMPLE 17

20 g of AlCl₃ was dissolved to 200 g of EtOH and TiCl₄ (9.48 g)+Ti(iOPr)₄ (14,21 g) was dissolved to 200 g of EtOH. Dissolved solutions were combined. Solution was stirred for 60 min at RT. EtOH was distilled using membrane pump, distillation apparatus and oil bath. 220g of 2-isopropoxyethanol was added to the material flask. The solution was cooled down to −6° C. 101.18 g of TEA was added in 10 min. Material solution temperature was kept between −6° C. and +6° C. during TEA addition. The solution was filtrated using a Buchner funnel. The solution was placed to the freezer over night. Finally the solution was filtrated using a filter paper. The solution was formulated to the final processing solvent EtOH and was ready for processing after final filtration.

### EXAMPLE 18

20 g of Aluminium s-butoxide and 200 g of PGEE were weighted to a round bottom flask and stirred at room temperature for 30 min. 15.58 g of Ethyl Acetoacetate was added drop-wise to the solution and stirring at room temperature was continued further 1 h. Mixture of H2O/PGEE (8 g/40 g) was added to the clear solution dropwise by Pasteur pipette and solution was stirred at room temperature overnight. The solid content of the material is 4.49 w-%

### EXAMPLE 19

To a round bottom flask containing 182.7 of ANN-DI water, 42.27 g of Aluminum-isopropoxide (AIP) power was added during 40 min under strong stirring. After AIP addition, 19.18 g of TEOS was added drop-wise during 30 min. The clear solution was stirred over a night at room temperature. Solution was heated up to 60° C. using an oil bath and condenser and stirred at 60° C. for 4 hours. After 4 hours clear solution was further stirred at room temperature for over a night.

Solvent exchange was carried out from DI water to 1-propanol using a rotary evaporator with three 1-propanol addition steps (Water bath temperature 60° C.). The total amount of added 1-propanol was 136 g. Total amount of removed solution was 195 g. After solvent exchange solid content of the solution was 16.85 w-%.

1. A method of passivating a silicon substrate, comprising
providing a silicon substrate having a surface;
forming a stack of passivating and anti-reflection coating layers on said surface by liquid phase deposition, wherein the passivating and anti-reflection coating layers comprise hydrogenated silicon oxide layers; and
providing at least titanium oxide or tantalum oxide capping layer on the stack opposite to the silicon substrate surface.

2. The method according to claim 1, wherein the passivating and anti-reflection coating layers comprise hydrogenated silicon oxide which releases hydrogen which is capable of causing a reduction in the surface and bulk recombination velocity of the silicon substrate.

3. The method according to claim 2, wherein the emitter saturation current (Joe) is less than 300 fA/cm2

4. The method according to claim 1, wherein the capping layer is capable of improving light absorption by the solar cell due to optical coupling with the layers underneath.

5. The method according to claim 1, wherein the passivating layer comprises silicon, oxygen and hydrogen for p type silicon substrate.

6. The method according to claim 1, wherein the anti-reflection layer comprises: titanium and oxygen for p type silicon substrate; tantalum and oxygen for p type silicon substrate; or aluminum and oxygen or aluminum, silicon and oxygen for p type silicon substrate.

7. (canceled)

8. (canceled)

9. The method according to claim 1, wherein the passivating layer is formed by polymerizing Si(OR¹)4 and/or HSi(OR¹)3, wherein R¹ is an alkyl group.

10. The method according to claim 9, wherein the alkoxy group is methoxy or ethoxy.

11. The method according to claim 1, wherein the hydrogen-releasing layer is formed by polymerizing: Si(OR¹)₄ and/or HSi(OR¹)₃ (for hydrogenated silicon oxide); Ti(iOPr)₄, HSi(OR¹)₃ and TiCl₄ (for titanium oxide); Ti(iOPr₅, HSi(OR¹)₃ and TaCl₅ (for tantalum oxide) or HSi(OR¹)₃ and Al(iOPr)₃ (for aluminium oxide and silicon oxide hybrid).

12. (canceled)

13. (canceled)

14. (canceled)

15. The method according to claim 1, wherein the passivating layer is capable of reducing the number of dangling bonds on the surface and bulk of the silicon substrate upon which the passivating layer is formed.

16. The method according to claim 1, wherein the anti-reflection layer is capable of increasing the absorption on a surface of the silicon substrate upon which the passivating layer is formed.

17. The method according to claim 1, wherein liquid phase deposition of the passivating layer is performed at atmospheric pressure.

18. The method according to claim 1, wherein the liquid phase coating is carried out by a method selected from the group of dip coating, slot coating, roller coating and spray coating and combinations thereof.

19. The method according to claim 1, wherein the silicon substrate is part of a photovoltaic cell.

20. The method according to claim 1, comprising vacuum depositing at least one SiNx layer in between either: the passivating and anti-reflection coatings; or the capping layers.

21. (canceled)

22. The method according to claim 20, wherein at least one SiNx layer is deposited by PECVD or sputtering.

23. The method according to claim 1, comprising forming at least one of the passivating and anti-reflection coatings or capping layers without a SiNx layer in between the coatings or capping layers, respectively.

24. A silicon substrate obtained by a process of passivating a silicon substrate, said process comprising:
providing a silicon substrate having a surface;
forming a stack of passivating and anti-reflection coating layers on said surface by liquid phase deposition, wherein the passivating and anti-reflection coating layers comprise hydrogenated silicon oxide layers and
providing at least titanium oxide or tantalum oxide capping layer on the stack opposite to the silicon substrate surface.

25. A photovoltaic device comprising
a silicon substrate having a first surface;
a stack of passivating and anti-reflection coating layers arranged on said surface, the passivating and anti-reflection coating layers comprising hydrogenated silicon oxide layers capable of releasing hydrogen; and
at least titanium oxide or tantalum oxide capping layer on the stack opposite to the silicon substrate surface.

26. The photovoltaic device according to claim 23, manufactured without using any vacuum deposition processes.
